(19) United States
(12) Patent Application Publication
(10) Pub. No.: US 2014/0242322 A1
(43) Pub. Date: Aug. 28, 2014

(54) ONE COMPONENT, DUAL-CURE ADHESIVE FOR USE IN ELECTRONICS

(71) Applicant: Albert M. Giorgini, Lino Lakes, MN (US)

(72) Inventor: Albert M. Giorgini, Lino Lakes, MN (US)

(73) Assignee: H.B. Fuller Company, St Paul, MN (US)

(21) Appl. No.: 14/233,843

(22) PCT Filed: Jul. 19, 2012
(86) PCT No.: PCT/US2012/047393

§ 371 Date: Apr. 9, 2014

Related U.S. Application Data
(60) Provisional application No. 61/510,806, filed on Jul. 22, 2011.

(51) Int. Cl. H05K 5/06; H05K 13/04

(52) U.S. Cl. CPC H05K 5/06; H05K 13/0469
USPC 428/76; 156/60; 156/275.5; 156/329; 156/331.7; 156/332

(57) ABSTRACT

The disclosure relates to one-component, dual-cure adhesive compositions that include a combination of moisture curable functionalities and radiation curable functionalities where the adhesive could include (1) a moisture-curable prepolymer and a radiation-curable component; or (2) a moisture curable radiation curable prepolymer including moisture curable functionalities and radiation curable functionalities, and optionally an additional moisture-curable prepolymer and/or an additional radiation-curable component. The disclosed adhesives can be used on substrates with electronic components to make electronic assemblies.

This application claims the benefit of U.S. Provisional Application No. 61/510,806, filed Jul. 22, 2012, which is incorporated herein.

### SUMMARY OF THE INVENTION

In some aspects, the present disclosure relates to a method of making an electronic assembly comprising a first substrate, a second substrate, and at least one electronic component located between the two substrates. The method includes providing a one component dual cure adhesive composition. The adhesive composition includes a moisture curable radiation curable prepolymer including moisture curable and radiation curable functionalities. The adhesive is applied to at least a portion of the first substrate. Then at least a portion of a second substrate is brought into contact with the adhesive on the first substrate. At least one of the first and second substrates includes at least one electronic component prior to applying the adhesive composition.

In some embodiments, the adhesive composition further includes an additional moisture-curable prepolymer and/or a radiation-curable component.

In some aspects, the present disclosure relates to a method of making an electronic assembly comprising a first substrate, a second substrate, and at least one electronic component located between the two substrates. The method includes providing a one component dual cure adhesive composition. The adhesive composition includes a moisture-curable prepolymer and a radiation-curable component. The adhesive is applied to at least a portion of the first substrate. Then at least a portion of the second substrate is brought into contact with the adhesive on the first substrate. At least one of the first and second substrates includes at least one electronic component prior to applying the adhesive composition.

In some embodiments, any one of the aforesaid methods further includes exposing the adhesive on the first substrate to radiation prior to or after contacting the adhesive on the first substrate with the second substrate.

In some aspects, the present disclosure relates to an electronic assembly that is prepared by any one of the aforesaid methods.

In one embodiment, the electronic assembly includes a first substrate, a second substrate, an electronic component located between the two substrates, and an adhesive composition that includes a dual cure reaction product of a moisture curable radiation curable prepolymer including moisture curable and radiation curable functionalities. At least a portion of the first substrate is bonded to at least a portion of the second substrate by the adhesive. In some embodiments, the adhesive composition includes a dual cure reaction product of the moisture curable radiation curable prepolymer including moisture curable and radiation curable functionalities, and an additional moisture-curable prepolymer and/or an additional radiation-curable component.

In one embodiment, the electronic assembly includes a first substrate, a second substrate, at least one electronic component located between the two substrates, and an adhesive composition that includes a dual cure reaction product of a moisture-curable prepolymer and a radiation-curable component. At least a portion of the first substrate is bonded to at least a portion of the second substrate by the adhesive.

In some embodiments, the aforesaid moisture curable prepolymer is a moisture curable aliphatic isocyanate terminated prepolymer.

### BRIEF DESCRIPTION OF THE DRAWINGS

FIG. 1 shows a cross-sectional view of an electronic component between two substrates.

FIG. 2 shows a cross-sectional view of an electronic component between two substrates with adhesive around the edges of the assembly.

FIG. 3 shows a cross-sectional view of an electronic component between two substrates with adhesive throughout the assembly.

### GLOSSARY

In reference to the invention, these terms have the meanings set forth below: “(Meth)acrylate” refers to acrylate, methacrylate, and mixtures thereof. “Dual cure” refers to a composition that cures through two different mechanisms, e.g., radiation on a radiation curable functionality and a chemical reaction between a moisture curable functionality (e.g., isocyanate functional group(s)) and moisture (or water).

“Aliphatic isocyanate terminated prepolymer” refers to an isocyanate terminated prepolymer that is a reaction product of an aliphatic isocyanate and a polyol.

### DETAILED DESCRIPTION OF THE INVENTION

### Adhesive Composition

The adhesive composition is a one-component, dual-cure adhesive. In some embodiments, the adhesive composition includes a mixture of a moisture-curable prepolymer and a radiation-curable component. In some embodiments, the adhesive composition includes a moisture curable radiation curable prepolymer including moisture curable functionalities and radiation curable functionalities. In some embodiments, the adhesive composition includes a mixture of a moisture curable radiation curable prepolymer including moisture curable functionalities and radiation curable functionalities, an additional moisture-curable prepolymer, and/or an additional radiation-curable component.

The adhesive is referred to as a “dual cure” adhesive because the adhesive is cured by exposure to moisture and radiation. In practice, the applied adhesive composition develops an initial lap shear strength through photopolymerizing or crosslinking of the ethylenically unsaturated groups on exposure to radiant energy, such as ultraviolet (UV) light. Such a composition maintains sufficient strength even at elevated temperatures in contrast to traditional hot-melt adhesives. While not wanting to be bound by any theory, the initial lap shear strength is attributed to polymerizing, upon exposing to radiation, a radiation curable functionality e.g., acrylate double bonds, thus creating a network, even though lightly crosslinked. The final properties of the adhesive composition result from subsequent reaction of the moisture curing functionalities with moisture.

The adhesive composition is a one component, liquid composition that can be easily applied at ambient temperature. The composition, after radiation energy exposure, preferably exhibits an initial lap shear strength of at least about 1 gram/square inch. The cured adhesive composition also preferably exhibits a peel strength of at least 25 g/lineal inch, or even a destructive bond to the substrate to which it is bonded. The composition preferably generates little to no volatile organic components and provides a moisture barrier and exhibits a moisture vapor transmission rate (MVTR) of no greater than about 20 gram/square meter/day (g/m²/day), or 15 g/m²/day, or 10 g/m²/day when in the form of a film having a thickness of about 60 mils. The composition preferably exhibits an elongation of at least about 10% or at least about 100%, and preferably exhibits a glass transition temperature (Tg) less than about 10° C., or −10° C.

When used with electronic assemblies, the adhesive preferably exhibits certain properties. For example, the adhesive is preferably capable of being processed at low temperatures on low cost substrates. It is preferably capable of being used in an automated roll-to-roll manufacturing process. It preferably exhibits a fast attach without requiring a B-stage. The composition preferably has a long open or long set time. The composition preferably exhibits good initial strength and final bond strength to low energy materials like plastics. It is preferably flexible. It preferably exhibits good moisture and oxygen barrier performance. It is preferably optically clear and does not yellow when exposed to UV radiation or higher temperatures. It preferably exhibits low outgassing and voids. And it preferably acts as a drying agent or desiccant by consuming residual moisture inside of the sealed assembly.

The adhesive compositions include at least one first functional group that is capable of polymerizing upon exposure to moisture (moisture-curable) and at least one second functional group that is capable of polymerizing upon exposure to radiation (radiation-curable). Non-limiting examples of moisture-curable functional groups include isocyanate functional groups, silane functional groups, and mixtures thereof. Non-limiting examples of radiation-curable groups include ethylenically unsatured groups such as acrylate, methacrylate, acryl groups (e.g., acrylamide and acryloxy), methacryl groups (e.g., methacrylamide and methacryloxy), and alkenyl groups (e.g., vinyl, allyl, and hexenyl). The functional groups can be located pendant, terminal, or a combination thereof. Preferably the functional groups are located terminally on the prepolymer, i.e., the prepolymer is endcapped with functional groups.

The number of reactive groups on the prepolymer is primarily controlled by the desired prepolymer(s) equivalent weight. The higher the molecular weight of the prepolymers, the higher the elongation of the final products. But, this in turn lowers the reactive functionality present to achieve the initial green strength. To obtain the desired properties, the functionality of the prepolymers has to be balanced by adjusting the molar equivalents of each component in the resulting prepolymer.

As discussed above, the adhesive composition includes a combination of moisture curable functionalities and radiation curable functionalities.

In one embodiment, the adhesive composition includes a mixture of a moisture-curable prepolymer and a radiation-curable component.

In one embodiment, the adhesive composition includes a moisture curable radiation curable prepolymer including moisture curable functionalities and radiation curable functionalities.

In one embodiment, the adhesive composition includes a mixture of a moisture curable radiation curable prepolymer including moisture curable functionalities and radiation curable functionalities, and an additional moisture-curable prepolymer and/or an additional radiation-curable component.

The moisture curable prepolymer, radiation curable component, and moisture curable radiation curable prepolymer including moisture curable functionalities and radiation curable functionalities will now be discussed in more detail.

Moisture Curable Prepolymer

The moisture-curable prepolymer can be an isocyanate terminated polyurethane prepolymer, or a silanated terminated prepolymer, or a combination thereof. The silanated terminated prepolymer includes a silanated terminated polyurethane prepolymer and other silanated terminated prepolymer that is not a polyurethane prepolymer. The isocyanate terminated or silanated terminated polyurethane prepolymer preferably has a number average molecular weight of from about 1500 to about 20,000 g/mole. Preferred isocyanate terminated polyurethane prepolymers are described in U.S. Pat. No. 6,355,317, incorporated herein by reference in its entirety. Preferred silanated terminated prepolymers as above described are end-capped with at least one silane functional group, and preferably include no greater than six silane functional groups. Most preferably, the moisture curable silanated terminated prepolymer has less than about 25% molar equivalents, most preferably less than about 20% molar equivalents, of silane groups, based on the molar equivalents of the prepolymer.

The moisture curable prepolymer is present in the adhesive composition in an amount from about 20% by weight, or about 30% by weight, to about 95% by weight, or to about 80% by weight, or to about 70% by weight, or to about 60% by weight, or to about 50% by weight, based on the weight of the composition.

The moisture curable prepolymers and the radiation curable component are preferably present in a weight ratio of from about 9:1 to about 1:9, or preferably from about 4:1 to about 1:4.

Isocyanate-Terminated Prepolymers

Isocyanate-terminated prepolymers are created by reacting isocyanates and polyols. Useful isocyanates to make the prepolymer include any suitable isocyanate having at least two isocyanate groups including, e.g., aliphatic, cycloaliphatic, araliphatic, arylalkyl, alkylaryl, and aromatic isocyanates, and mixtures thereof.

Preferred isocyanate-terminated prepolymers include those that are a reaction product of an aliphatic polyisocyanate and a polyol.

Suitable diisocyanates include, e.g., trimethylene diisocyanate, tetramethylene diisocyanate, hexamethylene diisocyanate, isophorone diisocyanate, pentamethylene diisocyanate, 2,4,4-trimethylhexamethylene diisocyanate, dodecamethylene diisocyanate, 2,2,4-trimethylhexamethylene diisocyanate, hexamethylene diisocyanate-trimer, dodecamethylene diisocyanate, 1,3-cyclopentane diisocyanate, 1,4-cyclohexane diisocyanate, 1,3-cyclohexane diisocyanate, 4,4′-methylenebis(cyclohexylisocyanate), methyl-2,4-cyclohexanediisocyanate, methyl-2,6-cyclohexanediisocyanate, 1,4-bis(isocyanatomethyl)cyclohexane, 3-isocyanatomethyl-3,5,5-trimethylcyclohexylisocyanate, 5-isocyanato-1-(isocyanatomethyl)-1,3,3-trimethyl-cyclohexane, 1,3-bis(isocyanatomethyl)cyclohexane, m-phenylene diisocyanate, p-phenylene diisocyanate, 4,4′-diphenyl diisocyanate, 1,5-naphthalene diisocyanate, 4,4′-diphenylmethane diisocyanate, diphenylmethane diisocyanate, 2,4-tolylene diisocyanate, 2,6-tolylene diisocyanate, 4,4′-toluidine diisocyanate, dianilidine diisocyanate, 4,4′-diphenyl ether diisocyanate, 1,3-xylylene diisocyanate, 1,4-xylylene diisocyanate, omega, omega′-diisocyanato-1,4-diethylbenzene, methylene bis(4-cyclohexyl isocyanate), tetramethylxylene diisocyanate, toluene diisocyanate, 4,4′ methylene diphenyl diisocyanate, blends of 2,4′ methylene diphenyl diisocyanate and 4,4′ methylene diphenyl diisocyanate, 2′,4′-diphenyl methane diisocyanate, and naphthalene-1,5-diisocyanate, and mixtures thereof. Other useful isocyanates are disclosed in, e.g., U.S. Pat. Nos. 6,387,449, 6,355,317, 6,221,978, 4,820,368, 4,808,255, 4,775,719, and 4,352,858, and incorporated herein.

Examples of other suitable diisocyanates include 1,2-diisocyanatoethane, 1,3-diisocyanatopropane, 1,2-diisocyanatopropane, 1,4-diisocyanatobutane, 1,5-diisocyanatopentane, 1,6-diisocyanatohexane, bis(3-isocyanatopropyl)ether, bis(3-isocyanatopropyl) sulfide, 1,7-diisocyanatoheptane, 1,5-diisocyanato-2,2-dimethylpentane, 1,6-diisocyanate-3-methoxyhexane, 1,8-diisocyanatoctane, 1,5-diisocyanato-2,2,4-trimethylpentane, 1,9-diisocyanatononane, 1,10-diisocyanatopropyl ether of 1,4-butylene glycol, 1,11-diisocyanatoundecane, 1,12-diisocyanatododecane, bis(isocyanatohexyl)sulfide, 4-diisocyanatobenzene, 1,3-diisocyanato-o-xylene, 1,3-diisocyanato-p-xylene, 1,3-diisocyanato-m-xylene, 2,4-diisocyanto-1-chlorobenzene, 2,4-diisocyanato-1-nitro-benzene, 2,5-diisocyanato-1-nitrobenzene, m-phenylene diisocyanate, 2,4-toluene diisocyanate, 2,6-toluene diisocyanate, mixtures of 2,4- and 2,6-toluene diisocyanate, 1,6-hexamethylene diisocyanate, 1,4-tetramethylene diisocyanate, 1,4-cyclohexane diisocyanate, hexahydrotoluene diisocyanate, 1,5-naphthalene diisocyanate, 1-methoxy-2,4-phenylene diisocyanate, 4,4′-cyclohexane diisocyanate, hexahydrotoluene diisocyanate, 1,5-napthalene diisocyanate, 1-methoxy-2,4-phenylene diisocyanate, 4,4′-diphenylmethane diisocyanate, 4,4′-biphenylene diisocyanate, 3,3′-dimethyl-4,4′-diphenylmethane diisocyanate, 3,3′-dimethyl-4,4′-diphenylmethane diisocyanate and 3,3′-dimethyldiphenylmethane-4,4′-diisocyanate and 3,3′-dimethyldiphenylmethane-4,4-diisocyanate.

Examples of suitable polyisocyanates include, e.g., triisocyanates, e.g., 4,4′,4″-triphenylmethane triisocyanate and 2,4,6-toluene triisocyanate, tetraisocyanates, e.g., 4,4′-dimethyl-2,2′-5,5′-diphenylmethane tetraisocyanate, and polymethylene polyphenylene polyisocyanate.

Particularly preferred diisocyanates are aliphatic isocyanate or blends of aliphatic isocyanates as they provide excellent UV stability (non-yellowing) and hydrolytic stability.

Useful aliphatic polyisocyanates include, e.g., 1,3-cyclopentane diisocyanate, 1,4-cyclohexane diisocyanate, 1,3-cyclohexane diisocyanate, hydrogenated MDI (i.e., dicyclohexylmethane diisocyanate, H₁₂-MDI), methyl 2,4-cyclohexanediisocyanate, methyl 2,6-cyclohexanediisocyanate, 1,4-bis(isocyanatomethyl)cyclohexane, 1,3-bis(isocyanatomethyl)cyclohexane.

Useful commercially available aliphatic isocyanates include, e.g., DESMODUR W, DESMODUR I, and DESMODUR N 3600, all from Bayer (Pittsburgh, Pa.) and VESTANAT IPDI and VESTANAT H12MDI from Evonik Degussa (Parsippany, N.J.).

Suitable polyols useful in the preparation of the prepolymer include, e.g., diols, triols and mixtures thereof. Preferred polyols include polyester polyols, polyolefin diols, polyether polyols, polydiene block polyols, and combinations thereof. Preferred polyols have a functionality of at least about 1.5, more preferably at least about 1.8, most preferably at least about 2, preferably no greater than about 4.0, more preferably no greater than about 3.5, most preferably no greater than about 3.0. Preferred polyols are amorphous, have a Tg less than about 0° C., preferably less than about −20° C., and a molecular weight greater than about 500 g/mole, more preferably from greater than about 500 g/mole to about 15,000 g/mole, most preferably from about 1000 g/mole to about 12,000 g/mole. Preferred polyols are hydrophobic, preferably predominantly hydrocarbon in structure.

Useful classes of polyols include, e.g., polyester polyols including, e.g., lactone polyols and the alkyleneoxide adducts thereof, and dimer acid-based polyester polyols, specialty polyols including, e.g., polybutadiene polyols, hydrogenated polybutadiene polyols, polycarbonate polyols, hydroxy alkyl derivatives of bisphenol A (e.g., bis(2-hydroxyethyl)bisphenol A), polythioether polyols, fluorinated polyether polyols, acrylic polyols, alkylene oxide adducts of polyphenols, polytetramethylene glycols, functional glycerides (e.g., castor oil), and polyhydroxy sulfide polymers.

Useful polyester polyols are prepared from the reaction product of polycarboxylic acids, their anhydrides, their esters or their halides, and a stoichiometric excess polyhydric alcohol. Suitable polycarboxylic acids include dicarboxylic acids and tricarboxylic acids including, e.g., aromatic dicarboxylic acids, anhydrides and esters thereof (e.g. phthalic acid, terephthalic acid, isophthalic acid, dimethyl terephthalate, diethyl terephthalate, phthalic acid, phthalic anhydride, methyl-hexahydrophthalic acid, methyl-hexahydrophthalic anhydride, methyl-tetrahydrophthalic acid, methyl-tetrahydrophthalic anhydride, hexahydrophthalic acid, hexahydrophthalic anhydride, and tetrahydrophthalic acid), aliphatic dicarboxylic acids and anhydrides thereof (e.g. maleic acid, succinic acid, succinic anhydride, glutaric acid, adipic acid, pimelic acid, suberic acid, azelaic acid, sebacic acid, chlorendic acid, 1,2,4-butane-tricarboxylic acid, decanedicarboxylic acid, octadecanedicarboxylic acid, dimeric acid, and fumaric acid), and alicyclic dicarboxylic acids (e.g. 1,3-cyclohexanedicarboxylic acid, and 1,4-cyclohexanedicarboxylic acid).

Examples of suitable polyols from which polyester polyols can be derived include ethylene glycols, propane diols (e.g., 1,2-propanediol and 1,3-propanediol), butane diols (e.g., 1,3-butanediol), 1,5-pentanediol, 1,6-hexanediol, 1,8-octanediol, 1,10-decanediol, neopentyl glycol, diethylene glycol, triethylene glycol, tetraethylene glycol, polyethylene glycols, polypropylene glycols (e.g., dipropylene glycol and tripropylene glycol) 1,4-cyclohexanedimethanol, 1,4-cyclohexanediol, dimer diols, bisphenol A, bisphenol F, hydrogenated bisphenol A, and hydrogenated bisphenol F, glycerol, and combinations thereof.

Examples of useful polyester polyols include polyglycol adipates, polyethylene terephthalate polyols, polycaprolactone polyols and polycaprolactone trials.

Suitable commercially available polyols include, e.g., dimer acid-based polyester polyols available under the PRIPLAST series of trade designations including, e.g., PRIPLAST 3187, 3190, 31%, and 3197 from Croda, polyester polyols available under the DESMOPHEN series of trade designations including, e.g., DESMOPHEN XF-7395-200, DESMOPHEN S-1011-P-210, DESMOPHEN S-1011-110, DESMOPHEN S-1011-55, and DESMOPHEN S-107-55 from Bayer Chemicals (Pittsburgh, Pa.). Exemplary polybutadiene polyols are available under the trade designations POLYBD R-20LM, R-45HT, and R-45M from Cray Valley. (, Pa.), and hydrogenated polybutadiene polyols available under the trade designation POLYTAIL from Mitsubishi Chemical Corp. (Japan).

Useful polyether polyols are prepared from polyoxyalkylenes. Nonlimiting examples of suitable polyether polyols include polyethylene oxide, polypropylene oxide, polytetramethylene ether glycol. Useful polyether polyols also include the reaction product of polyols and polyalkylene oxides. Useful polyols for preparing polyether polyols include ethylene glycol, propylene glycol, butanediols, hexanediols, glycerols, trimethylolethane, trimethylolpropane, and pentaerythritol, and mixtures thereof. Useful alkylene oxides for preparing polyether polyols include ethylene oxide, propylene oxide and butylene oxide and mixtures thereof. Suitable polyether polyols include the products obtained from the polymerization of a cyclic oxide, e.g., ethylene oxide, propylene oxide, butylene oxide, and tetrahydrofuran, or by the addition of one or more such oxides to polyfunctional initiators having at least two active hydrogens, e.g., water, polyhydric alcohols (e.g., ethylene glycol, propylene glycol, diethylene glycol, cyclohexane dimethanol, glycerol, trimethylol-propane, pentaerythritol and Bisphenol A), ethylenediamine, propylenediamine, triethanolamine, and 1,2-propanedithiol. Particularly useful polyether polyols include, e.g., polyoxypropylene diols and triols, poly(oxyethylene-oxypropylene)diols and triols obtained by the simultaneous or sequential addition of ethylene oxide and propylene oxide to appropriate initiators and polytetramethylene ether glycols obtained by the polymerization of tetrahydrofuran.

Silanated-Terminated Prepolymer

Silanated-terminated prepolymers are created by reacting a silane-functional compound having a reactive functionality capable of reacting with an isocyanate or a hydroxyl functionality (e.g., polyol). One useful organofunctional silane to make the prepolymer includes at least one functional group (e.g., hydrogen) that is reactive with an isocyanate group of the polyurethane prepolymer and has at least one silyl group. Another useful organofunctional silane to make the prepolymer includes at least one functional group that is reactive with a polyol or —OH terminated polyurethane and has at least one silyl group. Examples of useful silyl groups include alkoxysilyls, aryloxysilyls, alkyloxyiminosilyls, oxime silyls, and amino silyls.

Preferred hydrogen active organofunctional silanes include, e.g., aminosilanes (e.g., secondary amino-alkoxysilanes and mercapto-alkoxysilanes). Examples of suitable aminosilanes include phenyl amino propyl trimethoxy silane, methyl amino propyl trimethoxy silane, n-butyl amino propyl trimethoxy silane, t-butyl amino propyl trimethoxy silane, cyclohexyl amino propyl trimethoxy silane, dibutyl maleate amino propyl trimethoxy silane, dibutyl maleate substituted 4-amino 3,3-dimethyl butyl trimethoxy silane, amino propyl triethoxy silane and mixtures thereof. Specific examples of aminosilanes include N-methyl-3-amino-2-methylpropyltrimethoxysilane, N-ethyl-3-amino-2-methylpropyltrimethoxysilane, N-ethyl-3-amino-2-methylpropyldiethoxysilane, N-ethyl-3-amino-2-methylpropyltriethoxysilane, N-ethyl-3-amino-2-methylpropylmethyldimethoxysilane, N-butyl-3-amino-2-methylpropyltrimethoxysilane, 3-(N-methyl-3-amino-1-methyl-1-ethoxy) propyltrimethoxysilane, N-ethyl-4-amino-3,3-dimethylbutyldimethoxymethylsilane, N-ethyl-4-amino-3,3-dimethylbutyltrimethoxysilane, bis-(3-trimethoxysilyl-2-methylpropyl)amine, N-(3′-trimethoxysilylpropyl)-3-amino-2-methylpropyltrimethoxysilane, N,N-bis[(3-triethoxysilyl) propyl]amine, N,N-bis[(3-tripropoxy-silyl)propyl]amine, N-(3-trimethoxysilyl) propyl-3-[N-(3-trimethoxysilyl)-propylamino]propionamide, N-(3-triethoxysilyl) propyl-3-[N-3-triethoxysilyl)-propyl-amino]propionamide, N-(3-trimethoxysilyl) propyl-3-[N-3-triethoxysilyl)-propylamino]propionamide, 3-trimethoxysilylpropyl 3-[N-(3-trimethoxysilyl)-propylamino]-2-methyl propionate, 3-triethoxysilylpropyl 3-[N-(3-triethoxysilyl)-propylamino]-2-methyl propionate, 3-trimethoxysilylpropyl 3-[N-(3-triethoxysilyl)-propylamino]-2-methyl propionate, gamma-mercaptopropyl-trimethoxysilane and N,N′-bis((3-trimethoxysilyl)propyl)amine.

Useful commercially available aminosilanes include, e.g., aminosilanes available under the SILQUEST series of trade designations including, e.g., SILQUEST A-1170, SILQUEST A-1110, SILQUEST Y-9669 and SILQUEST A-15 from Momentive (Greenwich, Conn.), under the DYNASYLAN series of trade designations including, e.g., DYNASYLAN 1189 N-(n-butyl)aminopropyltrimethoxysilane and DYNASYLAN MTMO 3-mercaptopropyl trimethoxy silane both of which are available from Degussa Corporation (Naperville, Ill.), and under the SILQUEST A-189 gamma-mercaptopropyltrimethoxysilane trade designation from Momentive.

Useful isocyanato alkoxysilanes include, e.g., gamma-isocyanatopropyl-triethoxysilane and gamma-isocyanatopropyl-trimethoxysilane, commercially available examples of which are available under the trade designation SILQUEST A-35 and SILQUEST A-25 from Momentive.

Other useful silane capped polyurethanes are the PERMAPOL urethanes described in U.S. Pat. No. 4,960,844, and the silylated polyurethane compositions described in U.S. Pat. No. 6,498,210, incorporated herein by reference. Other useful silane functional moisture curable prepolymers that are not polyurethanes include silyl terminated polyethers, which are available under the trade name KANEKA MS POLYMER and KANEKA SILYL and silyl terminated polyisobutylene, trade name KANEKA EPION all available from Kaneka America Corporation (New York, N.Y.).

Radiation Curable Component

The radiation curable component is present in the adhesive composition in an amount of from about 5% by weight, or about 15% by weight, or about 20% by weight to about 80% by weight, or to about 60% by weight, based on the weight of the composition. The radiation curable component may be monomeric, oligomeric, or polymeric. An oligomer is a compound containing in general on average from 2 to 10 basic structures or monomer units. A polymer, in contrast, is a compound containing in general on average at least more than 10 basic structures or monomer units. The radiation curable component is preferably derived from acrylates, e.g., monomers, oligomers, and polymers of (meth)acrylate, or combinations thereof.

Suitable acrylates include (meth)acrylate esters including, e.g., esters of acrylic acid and methacrylic acid prepared from acrylic acid and/or methacrylic acid and aliphatic alcohols, aromatic polyols, aliphatic polyols, cylcoaliphatic polyols, and combinations thereof, (meth)acrylate esters of polyether alcohols, urethane(meth)acrylate oligomers, epoxy(meth)acrylate oligomers, and combinations thereof. The unmodified acrylate will generally have a number average molecular weight of from 500 to 50,000 g/mole, preferably from 1000 to 5000 g/mole.

Exemplary acrylate monomers include acrylate esters of aliphatic diols containing 2 to about 40 carbon atoms, such as neopentyl glycol di(meth)acrylate, 1,6-hexanediol di(meth)acrylate, trimethylol propane tri(meth)acrylate, pentaerythritol tetra(meth)acrylate and (meth)arylate esters of sorbitol and other sugar alcohols. These (meth)acrylate esters of aliphatic or cycloalphatic diols may be modified with an aliphatic ester or alkylene oxide. Exemplary acrylates modified by an aliphatic ester include neopentyl glycol hydroxypivalate di(meth)acrylate, caprolactone-modified neopentyl glycol hydroxypivalate di(meth)acrylates and the like. The alkylene oxide-modified acrylate compounds include, for example, ethylene oxide-modified neopentyl glycol di(meth)acrylates, propylene oxide-modified neopentyl glycol di(meth)acrylates, ethylene oxide-modified 1,6-hexanediol di(meth)acrylates or propylene oxide-modified hexane-1,6-diol di(meth)acrylates or mixtures of two or more thereof.

Acrylate monomers based on polyether polyols comprise, for example, neopentyl glycol-modified trimethylol propane di(meth)acrylates, polyethylene glycol di(meth)acrylates, polypropylene glycol di(meth)acrylates and the like. Trifunctional and higher acrylate monomers comprise, for example, trimethyl propane tri(meth)acrylate, pentaerythritol tri(meth)acrylate, dipentaerythritol tetra(meth)acrylate, dipentaerythritol penta(meth)acrylate, dipentaerythritol hexa(meth)acrylate, caprolactone-modified dipentaerythritol hex(meth)acrylate, pentaerythritol tetra(meth)acrylate, tris[(meth)acryloxyethyl]-isocyanurate, caprolactone-modified tris[(meth)acryloxyethyl]-isocyanurates or trimethyol propane tetra(meth)-acrylate or mixtures of these.

Preferred acrylates include tripropylene glycol diacrylate, neopentyl glycol propoxylate di(meth)acrylate, trimethylol propane tri(meth)acrylate and pentaerythritol triacrylate.

Exemplary acrylate esters of aliphatic alcohols include, e.g., isobornyl(meth)acrylate, 2-ethoxyethoxy ethyl(meth)acrylate, and combinations thereof. Useful acrylate esters of aliphatic diols include, e.g., neopentyl glycol di(meth)acrylate, 1,6-hexanediol di(meth)-acrylate, trimethylolpropane tri(meth)acrylate, pentaerythritol tetra(meth)acrylate, and (meth)acrylate esters of sorbitol and of other sugar alcohols. These (meth)acrylate esters of aliphatic and cycloaliphatic diols may be modified with an aliphatic ester or with an alkylene oxide. The acrylates modified by an aliphatic ester include, e.g., neopentyl glycol hydroxypivalate di(meth)acrylate, caprolactone-modified neopentyl glycol hydroxypivalate di(meth)acrylates, and combinations thereof. The alkylene oxide-modified acrylate compounds include, e.g., ethylene oxide-modified neopentyl glycol di(meth)acrylates, propylene oxide-modified neopentyl glycol di(meth)acrylates, ethylene oxide-modified 1,6-hexanediol di(meth)acrylates or propylene oxide-modified 1,6-hexanediol di(meth)acrylates, and combinations thereof.

Suitable polyfunctional (meth)acrylate monomers include, e.g., tripropylene glycol diacrylate, neopentyl glycol propoxylate di(meth)acrylate, trimethylolpropane tri(meth)acrylate, and pentaerythritol triacrylate, and combinations thereof.

Exemplary acrylate oligomers include acrylated polyesters, acrylated aromatic urethanes, aliphatic urethanes, vinyl acrylates, acrylated oils, and acrylated acrylics. Examples of acrylated aliphatic urethanes include those available under the trade designations PHOTOMER 6010 (MW=1500) from Henkel Corp. (Hoboken, N.J.), EBECRYL 8401 (MW=1000) and EBECRYL 8402 (MW=1000, urethane diacrylate) from UCB Radcure Inc. (Smyrna, Ga.), CN 9635, CN9645, and CN 9655, from Sartomer (Exton, Pa.).

Exemplary acrylate polymers include polybutadiene diacrylate, polybutadiene urethane diacrylate, mono-functional and multi-functional acrylates (i.e., acrylates and methacrylates), acrylated polyesters, acrylated aromatic urethanes, acrylated aliphatic urethanes, acrylated acrylics, and combinations or blends thereof.

Preferred acrylates are hydrophobic, predominantly of hydrocarbon structure, have a low Tg (preferably less than about 0° C., more preferably less than about −10° C.) and have sufficient compatibility with the moisture curable prepolymer. Such acrylates are commercially available under the trade designations BAC-45 from San Esters Corporation, a distributor of Osaka Organic Chemicals (Osaka, Japan), and CN302 from Sartomer (Exton, Pa.).

Moisture Curable Radiation Curable Prepolymers

The moisture curable radiation curable prepolymer includes moisture curable and radiation curable functional groups. Exemplary moisture curable functional groups include isocyanate and/or silane functional groups discussed above for the moisture curable prepolymer. The functional groups are located pendant, terminal or a combination thereof on the prepolymer. Preferably the functional groups are located terminally on the prepolymer, i.e., the prepolymer is end capped with functional groups. Examples of the radiation curable functionality on the moisture curable radiation curable prepolymer include monomers, oligomers, and polymers of (meth)acrylate, and combinations thereof, as described above for the radiation curable component.

The moisture curable radiation curable prepolymer preferably includes from about 5% by weight, or about 10% by weight to no greater than 50% by weight isocyanate and/or silane functional groups, and an amount of radiation curable functional groups sufficient to provide a composition that, upon exposure to radiation, exhibits a lap shear strength suitable for subsequent processing.

The ratio of the equivalents of radiation curable functional groups to moisture curable functional groups preferably is from about 0.1:1 to about 5:1, or from about 0.5:1 to about 4:1, or from about 0.6:1 to about 3:1, or about 1:1. The average functionality of the moisture curable radiation curable prepolymer is preferably at least about 1.8, or about 2, and no greater than about 8, or no greater than about 4. The number average molecular weight of the moisture curable radiation curable prepolymer is preferably from about 200 to about 100,000 g/mole, or from about 400 to about 50,000 g/mole, or from about 600 to about 10,000 g/mole.

Moisture curable radiation curable prepolymers include a reaction product of any one of the aforesaid moisture curable prepolymers and any one of the aforesaid radiation curable components.

In one embodiment, the moisture curable radiation curable prepolymer is preferably prepared by reacting a compound (e.g., an aforesaid radiation curable component) that includes an active hydrogen and a radiation curable functional group with a polyisocyanate prepolymer (e.g., an aforesaid moisture curable isocyanate terminated polyurethane prepolymer), preferably in the presence of excess isocyanate. Preferably the compound that includes an active hydrogen and a radiation curable functional group is reacted with the isocyanate functional prepolymer in an amount such that from about 10% to about 80%, or from about 20% to about 70%, or from about 30% to about 60% of the isocyanate groups on the isocyanate functional prepolymer are replaced with the compound that includes the active hydrogen and the radiation curable functional group.

The term “active hydrogen” refers to the active hydrogen on hydroxyl, amine, and mercapto functional groups.

Examples of radiation curable functional groups include acrylate, methacrylate, alkenyl groups (e.g., vinyl, allyl, and hexenyl), vinyl ethers, vinyl esters, vinyl amides, maleate esters, fumarate esters, and styrene functional groups and combinations thereof.

In another embodiment, the moisture curable radiation curable prepolymer is preferably prepared by reacting a compound that includes an active hydrogen and a radiation curable functional group with a polyisocyanate prepolymer, preferably in the presence of excess isocyanate, which can be capped with silanes. Suitable isocyanate and polyols and suitable organofunctional silanes are described above. Suitable compounds that include an active hydrogen and a radiation curable functional group include, e.g., hydroxyalkyl acrylates and methacrylates (e.g., 2-hydroxyethylacrylate (HEA), 2-hydroxyethylmethylacrylate (HEMA), 2-hydroxypropylacrylate, 3-hydroxypropylacrylate (HPA) and 2-hydroxypropyl methacrylate, 3-hydroxypropyl methacrylate, 1,3-dihydroxypropylacrylate and 2,3-dihydroxypmpylacrylate and methacrylate, 2-hydroxyethylacrylamide and methacrylamide, 2-hydroxybutyl(meth)acrylate, 4-hydroxybutyl(meth)acrylate, 2-hydroxy-3-phenyloxypropyl(meth)acrylate, 1,4-butanediol mono(meth)acrylate, 2-hydroxy alkyl(meth)acryloyl phosphates, 4-hydroxycyclohexyl(meth)acrylate, 1,6-hexanediol mono(meth)acrylate, neopentyl glycol mono(meth)acrylate, trimethylolpropane di(meth)acrylate, trimethylolethane di(meth)acrylate, pentaerythritol tri(meth)acrylate, dipentaerythritol penta(meth)acrylate; N-alkyl-N-hydroxyethylacrylamides and methacrylamides, hydroxyethyl-betacarboxyethylacrylate, hydroxyhexyl acrylate, and hydroxyoctyl methacrylate and mixtures thereof.

Useful hydroxyethylacrylates and hydroxypropylacrylates are commercially available from Dow Chemical (Midland Mich.) and Osaka Organic Chemical Industry Ltd. (Osaka, Japan). Useful hydroxybutyl acrylates are commercially available from Osaka Organic Chemical Industry Ltd. Useful hydroxy polyester acrylates are commercially available under the TONE MONOMER M-100 trade designation from Dow Chemical Company and VISCOAT 2308 from Osaka Organic Chemical Industry Ltd. Useful hydroxy polyether acrylates are commercially available under the ARCOL R-2731 trade designation from Bayer Chemicals (Pittsburgh, Pa.).

Other Additives

The adhesive can optionally include other additives including, for example, antioxidants, photoinitiators, plasticizers, tackifying agents, adhesion promoters, non-reactive resins, ultraviolet light stabilizers, catalysts, rheology modifiers, defoamers, biocides, corrosion inhibitors, dehydrators, organic solvents, colorants (e.g., pigments and dyes), fillers, surfactants, flame retardants, waxes, reactive plasticizers, thermoplastic polymers, tackifying agents, organofunctional silane adhesion promoters, and mixtures thereof.

The adhesive can optionally include a photoinitiator. Suitable photoinitiators are capable of promoting free radical polymerization, crosslinking, or both, of the ethylenically unsaturated moiety on exposure to radiation of a suitable wavelength and intensity. The photoinitiator can be used alone, or in combination with a suitable donor compound or a suitable coinitiator. The photoinitiator and the amount thereof are preferably selected to achieve a uniform reaction conversion, as a function of the thickness of the composition being cured, as well as a sufficiently high degree of total conversion so as to achieve the desired initial handling strength (i.e., green strength).

Useful photoinitiators include, e.g., “alpha cleavage type” photoinitiators including, e.g., benzyl dimethyl ketal, benzoin ethers, hydroxy alkyl phenyl ketones, benzoyl cyclohexanol, dialkoxy acetophenones, 1-hydroxycyclohexyl phenyl ketone, trimethylbenzoyl phosphine oxides, methyl thio phenyl morpholino ketones and morpholino phenyl amino ketones; hydrogen abstracting photoinitiators, which include a photoinitiator and a coinitiator, based on benzophenones, thioxanthenes, benzyls, camphorquinones, and ketocoumarins; and combinations thereof. Preferred photoinitiators include acylphosphine oxides including, e.g., bis(2,4,6-trimethylbenzoyl)-phenylphosphine oxide, bis(2,6-dimethoxybenzoyl)-(2,4,4-trim ethylpentyl)phosphine oxide, and 2,4,4-trimethylbenzoyl diphenylphosphine oxide.

Useful commercially available photoinitiators are available under the following trade designations IRGACURE 369 morpholino phenyl amino ketone, IRGACURE 819 bis(2,4,6-trimethylbenzoyl)-phenylphosphine oxide and its preferred form CGI819XF, IRGACURE CGI 403 bis(2,6-dimethoxybenzoyl)-(2,4,4-trimethylpentyl) phosphine oxide, IRGACURE 651 benzyl dimethyl ketal, IRGACURE 184 benzoyl cyclohexanol, DAROCUR 1173 hydroxy alkyl phenyl ketones, DAROCUR 4265 50:50 blend of 2-hydroxy-2-methyl-1-phenylpropan-1-one and 2,4,6-trimethylbenzoyldiphenylphosphine oxide, and CGI1700 25:75 blend of bis(2,6-dimethoxybenzoyl)-2,4,4-trimethylpentylphosphine and 2-hydroxy-2-methyl-1-phenylpropan-1-one, all of which are available from BASF.

The photoinitiator is preferably present in an amount sufficient to provide the desired rate of photopolymerization. The amount will depend, in part, on the light source, the thickness of the layer to be exposed to radiant energy and the extinction coefficient of the photoinitiator at the wavelength. Typically, the photoinitiator component will be present in an amount up to about 5% by weight, or from about 0.01% by weight to about 5% by weight, more preferably from about 0.01% by weight to about 1% by weight, based on the weight of the composition. The adhesive can optionally include a plasticizer. Suitable plasticizers include, e.g., phthalates, benzoates, sulfonamides, and mixtures thereof, and epoxidized soybean oil. Useful sources of dioctyl and diisodecyl phthalate include those available under the trade designations JAYFLEX DOP and JAYFLEX DIDP from Exxon Chemical. Useful dibenzoates are available under the trade designations BENZOFLEX 9-88, BENZOFLEX 50 and BENZOFLEX 400 from Eastman Chemical Co. Soybean oil is commercially available, e.g., from Dow Chemical under the trade designation FLEXOL EPO.

Plasticizer, when present, is preferably present in an amount of from about 0.25% by weight to about 10% by weight, no greater than about 5% by weight, no greater than about 3% by weight, or even from about 0.5% by weight to 2% by weight.

The adhesive can also optionally include a reactive plasticizer, i.e., a plasticizer that includes at least one functional group capable of reacting with the moisture reactive component of the moisture curable, radiation curable polyurethane prepolymer, or the moisture curable polyurethane prepolymer, or a combination thereof. The term “reactive plasticizer” encompasses plasticizer that becomes reactive with the moisture reactive groups of the polyurethane prepolymer or with itself upon exposure to moisture. Such reactive plasticizers include plasticizers that bear an active hydrogen group upon exposure to moisture. The reactive plasticizer preferably is selected to have functional groups similar to the functional group(s) of the polyurethane prepolymer, functional groups that will become reactive with the polyurethane prepolymer or the plasticizer, itself, after the composition is applied to a substrate or during its intended use, (e.g., upon exposure to ambient atmosphere, e.g., air, moisture or a combination thereof), or a combination of such functional groups. The reactive plasticizer is preferably selected to polymerize or crosslink the polyurethane prepolymer upon exposure to ambient conditions, e.g., moisture, air or a combination thereof. The reactive plasticizer can include any suitable reactive group including, e.g., alkoxy, isocyanate, aldimine, ketomine, bisoxazolidones, and combinations thereof.

Examples of useful reactive plasticizers capable of reacting with silane functional polyurethane prepolymers include plasticizers having alkoxysilyl reactive groups including, e.g., methoxysilyl, ethoxysilyl, propoxysilyl, and butoxysilyl, and acyloxysilyl reactive groups including, e.g., silyl esters of various acids including, e.g., acetic acid, 2-ethylhexanoic acid, palmitic acid, stearic acid, and oleic acid, and combinations thereof. Suitable reactive plasticizers also include polymers endcapped with the above-described alkoxysilyl groups. Such polymers include, e.g., polyalkylene oxides (e.g., polypropylene oxides), polyether-sulfide-urethanes (e.g., low molecular weight PERMAPOL urethanes from PRC and as disclosed, e.g., in U.S. Pat. No. 4,960,844), polyisoalkylene oxides (e.g., polyisobutylene oxide), polyglycols, polyisobutylene, and combinations thereof.

Useful reactive plasticizers capable of reacting with isocyanate functional polyurethane prepolymers include, e.g., aldimines, ketimines, oxazolidines (e.g., bisoxazolidines, 1-(hydroxyethyl)-2-isopropyl-1,3-oxazolidine and 2-isopropyl-1,3-oxazolidine), dioxolanes (e.g., 2,2-dimethyl-1,3-dioxolane, 2,2-dimethyl-4-hydroxymethyle-1,3-dioxolane), and combinations thereof.

The reactive plasticizer preferably has a molecular weight of from about 300 g/mol to about 10,000 g/mol, more preferably from about 500 g/mol to about 6000 g/mol.

The reactive plasticizer is present in the composition in an amount of no greater than about 20% by weight, preferably from about 2% by weight to about 15% by weight, more preferably from about 3% by weight to about 10% by weight.

Suitable reactive plasticizers are curable with actinic radiation or thermally. If used, the reactive plasticizers are preferably curable with actinic radiation and most preferably with UV radiation. Exemplary reactive plasticizers are positionally isomeric diethyloctanediols or hydroxyl-containing hyperbranched compounds or dendrimers, or polycarbonatediols, polyesterpolyols, poly(meth)-acrylatediols or hydroxyl-containing polyadducts.

Examples of suitable reactive solvents that may be used as reactive plasticizers include, but are not limited to, butyl glycol, 2-methoxypropaol, n-butanol, methoxybutanol, n-propanol, ethylene glycol monomethyl ether, ethylene glycol monobutyl ether, ethylene glycol monobutyl ether, diethylene glycol monomethyl ether, diethylene glycol diethyl ether, diethylene glycol monobutyl ether, trimethylolpropane, ethyl 2-hydroxylpropionate or 3-methyl-3-methoxybutanol and also derivatives based on propylene glycol, e.g., ethoxyethyl propionate, isopropoxypropanol or methoxypropyl acetate.

Preferred reactive plasticizers include (meth)acrylic acids and esters thereof, maleic acid and its esters, including monoesters, vinyl acetate, vinyl ethers, vinylureas, and the like. Further examples include alkylene glycol di(meth)acrylate, polyethylene glycol di(meth)acrylate, 1,3-butanediol di(meth)acrylate, vinyl(meth)acrylate, allyl(meth)-acrylate, glycerol tri(meth)acrylate, trimethylol-propane tri(meth)acrylate, trimethylolpropane di(meth)-acrylate, styrene, vinyl toluene, divinylbenzene, pentaerythritol, tri(meth)acrylate, pentaerythritol tetra(meth)acrylate, dipentaerythritol penta(meth)acrylate, propylene glycol di(meth)acrylate, hexanediol di(meth)acrylate, ethoxyethoxyethyl acrylate, N-vinylpyrrolidone, phenoxyethyl acrylate, dimethylaminoethyl acrylate, hydroxyethyl(meth)acrylate, butoxyethyl acrylate, isobornyl(meth)acrylate, dimethylacrylamide, dicyclopentyl acrylate, the long-chain linear diacrylates described in EP 0 250 631 A1 with a molecular weight of from 400 to 4000, preferably from 600 to 2500. For example, the two acrylate groups may be separated by a polyoxybutylene structure. It is also possible to use 1,12-dodecyl propanediol and the reaction product of 2 moles of acrylic acid with one mole of a dimer fatty alcohol having generally 36 carbon atoms. Mixtures of the aforementioned monomers are also suitable.

The adhesive can optionally include a catalyst. Suitable catalysts facilitate the reaction between the polyol and polyisocyanate, hydrolysis, and/or the subsequent crosslinking reaction of the silane groups, isocyanate groups, or a combination thereof. Useful catalysts include, e.g., tertiary amines including, e.g., N,N-dimethylaminoethanol, N,N-dimethyl-cyclohexamine-bis(2-dimethyl aminoethyl)ether, N-ethylmorpholine, N,N,N′,N′,N″-pentamethyl-diethylene-triamine, and 1-2(hydroxypropyl) imidazole, and metal catalysts including, e.g., tin (e.g., dialkyl tin dicarboxylates, e.g., dibutyl tin dilaurate and dibutyl tin diacetate, stannous salts of carboxylic acids, e.g., stannous octoate and stannous acetate, tetrabutyl dioleatodistannoxane), titanium compounds, bismuth carboxylates, organosilicon titantates, alkyltitantates, and combinations thereof.

For moisture curable, radiation curable compositions, the catalyst is preferably present in an amount of from about 0.04% by weight to about 2% by weight.

The adhesive can optionally include a filler. Suitable fillers include, e.g., fumed silica, precipitated silica, talc, calcium carbonates, carbon black, alumina silicates, clay, zeolites, ceramics, mica, titanium dioxide, and combinations thereof. When present, the adhesive preferably includes filler in an amount of at least 0.5% by weight, from about 1% by weight to about 50% by weight, or even from about 5% by weight to about 10% by weight. For most applications, no filler would be used to maintain transparency.

The adhesive can optionally include a thermoplastic polymer. Commercially available thermoplastic polymers include, e.g., atactic polypropylene copolymers available under the REXTAC series of trade designations including, e.g., REXTAC RT 2535 and RT 2585, from Rexene Products Co. (Dallas, Tex.) and the EASTOFLEX series of trade designations including, e.g., EASTOFLEX E1060, from Eastman Chemical Co. (Kingsport, Term.); ethylene vinyl acetate copolymers available under the ELVAX series of trade designations from DuPont de Nemours (Wilmington, Del.) and the ULTRATHENE series of trade designations from Millennium Petrochemicals (Rolling Meadows, Ill.); ethylene methyl acrylate copolymers available under the OPTEMA series of trade designations from Exxon Chemical Co. (Houston, Tex.); ethylene n-butyl acrylate copolymers available under the LOTRYL series of trade designations from Sartomer (Philadelphia, Pa.), the ESCORENE series of trade designations from Exxon Chemical Co. and the ENATHENE series of trade designations from Millennium Petrochemicals; ethylene n-butyl acrylate carbon monoxide terpolymers available under the ELVALOY series of trade designations from DuPont; thermoplastic polyurethane polymers available under the PEARLSTICK series of trade designations from Aries Technologies (Derry, N.H., a distributor for Merquinsa, Barcelona, Spain); butylene/poly(alkylene ether) phthalate polymers available under the HYTREL series of trade designations from DuPont; ethylene acrylate copolymers also available under the ELVALOY series of trade designations from DuPont; and acrylic polymers available under the ELVACITE series of trade designations from ICI Acrylics (St. Louis, Mo.).

The thermoplastic polymer is present in the composition in an amount of from about 0% by weight to about 15% by weight, preferably from about 0% by weight to about 10% by weight.

The adhesive can optionally include a tackifying agent. Preferred tackifying agents have a ring and ball softening point of from about 70° C. to about 120° C., more preferably from about 80° C. to about 100° C. Examples of suitable tackifying agents include aliphatic, cycloaliphatic, aromatic, aliphatic-aromatic, aromatic modified alicyclic, and alicyclic hydrocarbon resins and modified versions and hydrogenated derivatives thereof; terpenes (polyterpenes), modified terpenes (e.g., phenolic modified terpene resins), hydrogenated derivatives thereof and mixtures thereof; natural and modified rosins such as gum rosin, wood rosin, tall oil rosin, distilled rosin, hydrogenated rosin, dimerized rosin and polymerized rosin; rosin esters including, e.g., glycerol and pentaerythritol esters of natural and modified rosins (e.g., glycerol esters of pale, wood rosin, glycerol esters of hydrogenated rosin, glycerol esters of polymerized rosin, pentaerythritol esters of hydrogenated rosin and phenolic-modified pentaerythritol esters of rosin); alpha methyl styrene resins and hydrogenated derivatives thereof; low molecular weight polylactic acid; and combinations thereof. Other useful tackifying agents are disclosed in, e.g., U.S. Pat. No. 6,355,317, and incorporated herein.

Suitable commercially available tackifying agents include, e.g., partially hydrogenated cycloaliphatic petroleum hydrocarbon resins available under the EASTOTAC series of trade designations including, e.g., EASTOTAC H-100, H-115, H-130 and H-142 from Eastman Chemical Co. (Kingsport, Term.) available in grades E, R, L and W, which have differing levels of hydrogenation from least hydrogenated (E) to most hydrogenated (W), the ESCOREZ series of trade designations including, e.g., ESCOREZ 5300 and ESCOREZ 5400 from Exxon Chemical Co. (Houston, Tex.), and the HERCOLITE 2100 trade designation from Hercules (Wilmington, Del.); partially hydrogenated aromatic modified petroleum hydrocarbon resins available under the ESCOREZ 5600 trade designation from Exxon Chemical Co.; aliphatic-aromatic petroleum hydrocarbon resins available under the WINGTACK EXTRA trade designation; styrenated terpene resins made from d-limonene available under the ZONATAC 105 LITE trade designation from Arizona Chemical Co. (Panama City, Fla.); aromatic hydrogenated hydrocarbon resins available under the REGALREZ 1094 trade designation from Hercules; and alphamethyl styrene resins available under the trade designations KRISTALEX 3070, 3085 and 3100, which have softening points of 70° C., 85° C., and 100° C., respectively, from Hercules.

For those adhesive compositions that include ethylene vinyl acetate, the tackifying agent is preferably selected based upon the vinyl acetate content of the ethylene vinyl acetate copolymer. For ethylene vinyl acetate copolymers having a vinyl acetate content of at least 28% by weight, the tackifying agent is preferably an aromatic or aliphatic-aromatic resin having a ring and ball softening point of from 70° C. to about 120° C. For vinyl acetate copolymers having a vinyl acetate content less than 28% by weight, the tackifying agent is preferably aliphatic or aliphatic-aromatic resin having a ring and ball softening point of from 70° C. to about 120° C.

The tackifying agent is present in the composition in an amount of from about 0% by weight to about 10% by weight, preferably from about 0% by weight to about 5% by weight.

### Methods of Making and Using

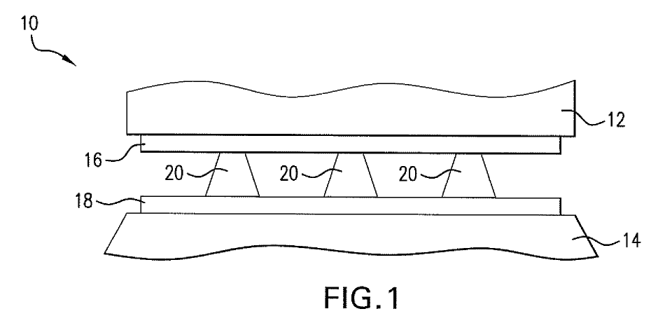

The disclosed adhesive can be used throughout the electronic manufacturing process. In some embodiments, the adhesive is used to bond multiple layers of an assembly together. An exemplary multi-layered assembly is shown in FIG. 1. FIG. 1 shows a general assembly 10. The assembly 10 includes a first substrate 12 and a second substrate 14. The assembly 10 includes at least one electronic component 20 located between substrate 12 and substrate 14. It is understood that the assembly 10 can include more than one electronic component 20 as shown in FIG. 1.

The assembly 10 can optionally include a conductive layer 16 and 18 located between the electronic component 20 and the substrates 12 and 14. The conductive layer can be a conductive coating, a conductive ink, or a conductive adhesive. The conductive layer can be continuous along the substrate or discontinuous. An exemplary conductive layer is indium-tin-oxide (ITO). The electronic component 20 may be placed between the first substrate 12 and second substrate 14 in such a way as to be in direct or indirect electrical communication with the conductive layers 16 and 18. Direct communication can be intimate contact and indirect communication can be through a conductive material or medium. It may be desirable for one side of the electronic component to correspond to an anode side and the other side to correspond to a cathode side.

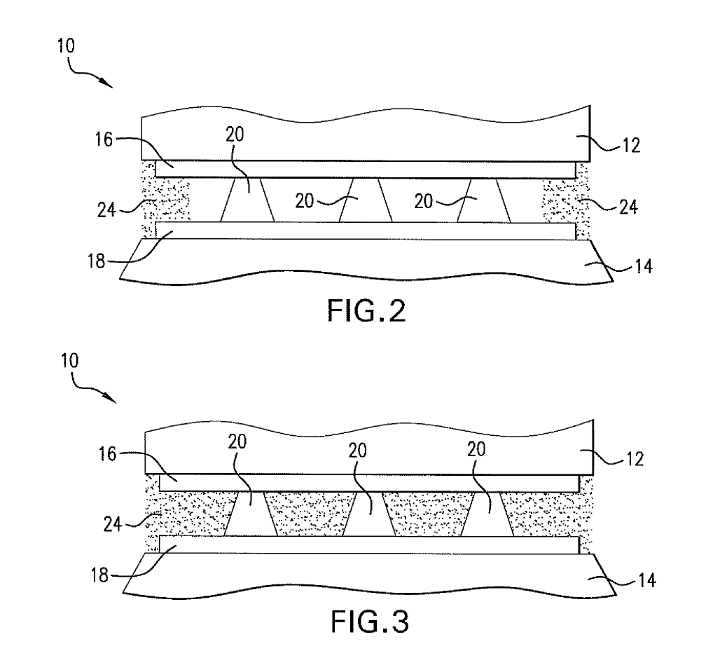

The adhesive can be used to bond or seal the layers of the assembly 10 together either by applying adhesive 24 to the edges of the assembly, as shown in FIG. 2, or by flooding the assembly with adhesive 24 as shown in FIG. 3.

The disclosed adhesive compositions can be used to manufacture electronic assemblies. When used with electronics, the adhesive composition can also function as a conductive adhesive, semi-conductive adhesive, insulative adhesive, or sealant. The assembly can include a variety of electronic components. Exemplary electronic components include light-emitting diodes (LEDs), organic LEDs, high brightness LEDs, radio frequency identification (RFID) tags, electrochromatic displays, electrophoretic displays, batteries, sensors, solar cells, and photovoltaic cells.

Using adhesives to adhere substrates together or seal electronics between two substrates can provide benefits like protection from elements such as moisture, UV radiation, oxygen, and the like. It can also provide protection from off-gasses from the materials in the assembly. It can also allow electrons to travel between the two substrates.

In some embodiments, the disclosed adhesives can be used to laminate various electronic components between two flexible substrates. In particular, the adhesive can be used to bond at least two substrates together, at least one of the substrates has at least one electronic component thereon prior to applying the adhesive. Exemplary lamination processes include roll-to-roll manufacturing processes. The adhesive can be applied to a substrate in a variety of ways. For example, the adhesive can be applied in the liquid state. The adhesive may be applied using any suitable coating process including, e.g., air knife, jetting, trailing blade, spraying, brushing, dipping, doctor blade, roll coating, gravure coating, offset gravure coating, rotogravure coating, linear extruder, hand gun, extruder beads, and combinations thereof. The adhesive can also be printed on in a predetermined pattern. The adhesive can also be applied to a release liner where the adhesive/liner composite is adhered to a substrate.

The adhesive compositions are preferably a liquid at room temperature. Useful coating temperatures range from 65° F. to 170° F. The coat weight of the adhesive may vary broadly depending on the properties desired of the laminate. Once coated on at least a portion of a first substrate with the adhesive, the first substrate is contacted with a second substrate. At least one of the substrates has at least one electronic component thereon prior to applying the adhesive. The second substrate may be of the same or different material relative to that of the first substrate but is sufficiently transparent to UV radiation. The bonding/laminating process may be repeated a number of times, so that it is possible to produce laminated articles which consist of more than two bonded layers.

In one embodiment, the method of making an electronic assembly includes coating a first substrate with the one component dual cure adhesive composition, exposing the coated adhesive composition to radiation, then contacting the coated adhesive composition on the first substrate with a second substrate. At least one of the substrates has at least one electronic component thereon prior to applying the adhesive. In another embodiment, the method of making an electronic assembly includes coating a first substrate with the one component dual cure adhesive composition, bringing a second substrate into contact with the coated adhesive on the first substrate, and then exposing the laminated two substrates to radiation. At least one of the substrates has at least one electronic component thereon prior to applying the adhesive.

Exposing the adhesive composition to radiation can occur before, after or combinations thereof, contacting the coated adhesive on the first substrate with the second substrate. The adhesive composition can be directly exposed to radiation or exposed to radiation through at least one of the substrates, where the substrate is sufficiently transparent to ultraviolet radiation. Exposing the adhesive composition to radiation initiates free radical polymerization of the radiation curable functional groups present in the composition, which imparts initial adhesive properties, e.g., lap shear strength, to the laminate. A relatively slower chemical reaction involving the isocyanate and/or silane groups and moisture present in the composition also occurs over time and provides the final performance properties of the cured adhesive composition and the laminated assembly constructed therewith.

The adhesive composition can be radiation cured using, e.g., electron beam, ultraviolet light (i.e., radiation in the range from about 200 nm to about 400 nm), visible light (radiation having a wavelength in the range of from about 400 nm to about 800 nm) and combinations thereof. Useful sources of radiation include, e.g., extra high pressure mercury lamps, high pressure mercury lamps, medium pressure mercury lamps, metal halide lamps, microwave powered lamps, xenon lamps, laser beam sources including, e.g., excimer lasers and argon-ion lasers, and combinations thereof.

In some embodiments, the disclosed adhesives can be used to seal electronic components to provide further protection. In such applications the adhesive can be applied to the edges of the substrates only, or can be applied to the entire surface of the substrate, thereby encapsulating the electronic component. The adhesive can be applied using any of the processes described above.

In some embodiments, the disclosed adhesives can be used to bond electronic components together as part of a manufacturing process. This application is similar to the laminating process in that two substrates are being bonded together. But, this process may be used with rigid and flexible substrates.

### Substrates

The disclosed adhesive composition can be used with a variety of rigid or flexible substrates. Exemplary substrates include flexible films such as metal foils (e.g., aluminum foil), polymer films and metallized polymer films prepared from polymers including, e.g., polyolefins (e.g., polypropylene, polyethylene, low density polyethylene, linear low density polyethylene, high density polyethylene, polypropylene, and oriented polypropylene; copolymers of polyolefins and other comonomers) metalized polyolefins (e.g., metalized polypropylene), metalized polyether terephthalate, ethylene-vinyl acetates, ethylene-methacrylic acid ionomers, ethylene-vinyl-alcohols, polyesters, e.g. polyethylene terephthalate, polycarbonates, polyamides, e.g. Nylon-6 and Nylon-6,6, polyvinyl chloride, polyvinylidene chloride, polylactic acid, cellulosics, and polystyrene, cellophane, and paper. The thickness of a film may vary, but flexible films typically have a thickness of less than about 0.50 millimeters, e.g. from about 10 micrometers to about 150 micrometers, more typically from about 8 micrometers to about 100 micrometers. The surface of the substrate can be surface treated to enhance adhesion using any suitable method including, e.g., corona treatments, chemical treatments and flame treatments.

Other suitable substrates include, e.g. woven webs, non-woven webs, paper, paperboard, and cellular flexible sheet materials (e.g., polyethylene foam, polyurethane foam and sponge and foam rubber). Woven and non-woven webs can include fibers including, e.g., cotton, polyester, polyolefin, polyamide, and polyimide fibers.

Other substrates can include glass, transparent plastics such as polyolefins, polyethersulfones, polycarbonates, polyester, polyarylates, and polymeric films.

For a more complete understanding of the disclosure, the following examples are given to illustrate some embodiments. These examples and experiments are to be understood as illustrative and not limiting. All parts, ratios, percents, and amounts stated in the examples are by weight unless otherwise specified.

### EXAMPLES

### Test Methods

### Lap Shear Strength

Lap shear strength is determined according to ASTM D3163 in which the test specimen is constructed to have 5 mil coating of an adhesive on a first 10 mil thick polyethylene terephthalate (PET) substrate laminated to a second 10 mil thick polyethylene terephthalate (PET) substrate with a 1 inch×1 inch substrate overlap.

The Maximum Load is determined and results are reported as lap shear strength in units of g/in². Reporting an average of three samples.

### Moisture Vapor Transmission Rate (MVTR)

Moisture vapor transmission rate (MVTR) is determined according to ASTM F1249-90 entitled, “Standard Test Method for Water Vapor Transmission Rate Through Plastic Film and Sheeting using a Modulated Infrared Sensor.” The test is conducted at approximately 37° C. (100° F.) and 90% relative humidity on an adhesive sample in the form of a film having a specified thickness.

### Elongation

Elongation is determined according to ASTM D638, entitled, “Standard Test Method for Tensile Properties of Plastics.”

### Peel Adhesion Test Method

T-peel strength is determined according to ASTM D1876-01 entitled, “Standard Test Method for Peel Resistance of Adhesives,” in which the test specimen is constructed to have 5 mil coating of adhesive on a first 10 mil thick polyethylene terephthalate (PET) substrate laminated to a second 10 mil thick polyethylene terephthalate (PET) substrate with a 1 inch×1 inch substrate overlap.

The peel speed is 12 inches per minute. The results are reported in grams per lineal inch. Reporting an average of three samples.

### Glass Transition Temperature (Tg)

The glass transition temperature (Tg) of an uncured adhesive composition is determined according to ASTM D-3418-83 entitled, “Standard Test Method for Transition Temperatures of Polymers by Differential Scanning calorimetry (DSC)” by conditioning a sample at 60° C. for two minutes, quench cooling the sample to −60° C. and then heating the ample to 60° C. at a rate of 20° C. per minute. The reported Tg is the temperature at which onset of the phase change occurs. For cured compositions, Tg is measured as the peak temperature of the Tand curve obtained by DSC.

### % NCO

Isocyanate percentage (% NCO) present in the adhesive composition is determined by first dissolving the prepolymer in toluene, reacting a predetermined volume of the prepolymer/toluene solution with a predetermined volume of a dibutylamine solution. The amine reacts with the isocyanate groups. The excess amine is then titrated with a predetermined solution of hydrogen chloride. The volume of the hydrogen chloride solution is then used to calculate the % NCO present in the composition.

### Examples

### Prepolymers and Components

The following Prepolymers and Components were used for making the adhesives to be tested in the Examples:

### Moisture Curable Isocyanate Terminated Prepolymer A

To make the Prepolymer A, 377 grams of DESMOPHEN S-107-55 (a polyester polyol, % moisture<0.05%) was added to a clean dry reactor and then heated to 180° F. while stirring under full vacuum (>28″ Hg) until bubbling stopped. Then, while stirring under nitrogen blanket, 174 grams DESMODUR W (dicyclohexylmethane diisocyanate), 0.06 grams DABCO T-12 (catalyst), and 0.06 grams MODAFLOW (flow agent), was added, the reaction was resealed, heat was maintained 180° F., and the mixture was allowed to mix under full vacuum for 3 hours. The final % NCO of the prepolymer was checked and found to be 7.17%. The resulting prepolymer was discharged and stored under a blanket of dry nitrogen.

### Moisture Curable Radiation Curable Prepolymer B

To make the Prepolymer B, 935.23 grams of ACCLAIM 12200 (PPG polyol) was added to a clean dry reactor and heated to 180° F. while stirring under full vacuum. Then, 124.3 grams of DESMODURE W (Dicyclohexylmethane diisocyanate), 0.12 grams of DABCO T-12 (catalyst), 0.12 grams of MODAFLOW (flow agent), and 0.12 grams of 85% phosphoric acid were added while slowly stirring under a nitrogen blanket. The mixture was resealed, heat was maintained at 180° F., and the mixture was mixed under full vacuum for 3 hours. The final % NCO of the prepolymer was checked and found to be 3.14%. The mixture was cooled to 160° F. and then 40.2 grams of 2-Hydroxyethylacrylate (2HEA) was added while slowly stirring. The reactor was resealed and the mixture was stirred under a partial (20″ Hg) vacuum for 1.5 hours and then checked for the final % NCO, which was found to be 1.80%. The prepolymer was discharged and stored.

### Moisture Curable Radiation Curable Prepolymer B2

To make the Prepolymer B2, 491.81 grams of ACCLAIM 12200 (PPG polyol) was added to a clean dry reactor and heated to 180° F. while stirring under full vacuum. Then, 92.54 grams of DESMODUR N3600 (homopolymer of hexamethylene diisocyanate), 0.06 grams of DABCO T-12 (catalyst), 0.06 grams of MODAFLOW (flow agent), and 0.06 grams of 85% phosphoric acid were added while slowly stirring under a nitrogen blanket. The mixture was resealed, heat was maintained at 180° F., and the mixture was mixed under full vacuum for 3 hours. The final % NCO of the prepolymer was checked and found to be 3.01%. The mixture was cooled to 160° F. and then 15.48 grams of 2-Hydroxyethylacrylate (2HEA) was added while slowly stirring. The reactor was resealed and the mixture was stirred under a partial (20″ Hg) vacuum for 1.5 hours and then checked for the final % NCO, which was found to be 2.00%. The prepolymer was discharged and stored.

### Radiation Curable Component C

Radiation curable component (C) is GENOMER 1121 (acrylic monomer, molecular weight of 208).

### Radiation Curable Component C1

Radiation curable component C1 is GENOMER 1121 M (acrylic monomer, molecular weight of 222).

### Example 1

To make the adhesive composition of Example 1, 50 grams of Prepolymer A, 122 grains of Prepolymer B, 23 grains of Component (C) (GENOMER 1121, acrylic monomer), 4.94 grams of GENOCURE LTM (photoinitiator), and 0.2 grams DABCO T-12 (catalyst) were added to a clean dry reactor at room temperature and mixed under vacuum for 30 minutes. The resulting adhesive composition was discharged and stored under a blanket of dry nitrogen.

Approximately 15-20 mils of the adhesive composition was coated onto a particle board. An initial touch with a gloved finger found no surface tack and a completely fluid liquid. The coated board was exposed to UV radiation from a medium pressure mercury lamp having a power of 300 watts per inch at a conveyer line speed of 33, 50 and 100 feet per minute. The adhesive was again touched with a gloved finger and in all three cases the material had cured to a non fluid state and was tacky to the touch, with the level of tack increasing with line speed. A plastic film was applied to the tacky adhesive surface and when turned upside down the plastic film was held in place, upon peel back the plastic film, legging was observed indicating a cohesive bond had developed. After a period of 7 days under ambient conditions, the film could no longer be removed without being destroyed and the surface tack completely disappeared.

### Examples 2-8

Each of the adhesive compositions of Examples 2-8 was prepared according to the procedures in Example 1 using various combinations of a moisture curable prepolymer, a radiation curable component and a moisture curable radiation curable prepolymer, as shown in Table 1.

Laminate 1 of each of Examples 2-8 was prepared according to herein described Lap Shear Strength and Peel Adhesion test methods by coating each of the adhesive compositions of Examples 2-8 on the first PET substrate, then laminating the coated first substrate with the second substrate. Thereafter, the laminate was exposed to radiation from a medium pressure mercury lamp having a power of 300 watts per inch at a conveyor speed of 100 feet per minute.

Laminate 2 of each of Example 2-8 was prepared in the same way as that of Laminate 1, except exposing the coated adhesive on the first substrate to radiation first. Then, the first substrate with partially cured adhesive composition was laminated with the second PET substrate.

Laminates 1 and 2 of Examples 2-8 were tested according to the herein described Lap Shear Strength test method and the Peel Strength test method, and the results are set forth in Tables 2 and 3 below.

TABLE 1

| | Wt % | | | | | | |
|---|---|---|---|---|---|---|---|
| | Ex 2 | Ex 3 | Ex 4 | Ex 5 | Ex 6 | Ex 7 | Ex 8 |
| Prepolymer A | 25 | 25 | 25 | 82.5 | 82.5 | | |
| Prepolymer B | 61 | | 61 | | | 82.5 | 82.5 |
| Prepolymer B2 | | 61 | | | | | |
| Component (C1) | 11.5 | 11.5 | | 15 | | 15 | |
| Component (C) | | | 11.5 | | 15 | | 15 |
| Photoinitiator | 2.4 | 2.4 | 2.4 | 2.4 | 2.4 | 2.4 | 2.4 |
| Catalyst | 0.1 | 0.1 | 0.1 | 0.1 | 0.1 | 0.1 | 0.1 |
| Total | 100 | 100 | 100 | 100 | 100 | 100 | 100 |

TABLE 2
T-Peel Strength and Lap Shear Strength of Laminate 1 of Examples 2-8

| | Ex 2 | Ex 3 | Ex 4 | Ex 5 | Ex 6 | Ex 7 | Ex 8 |
|---|---|---|---|---|---|---|---|
| T-Peel Strength | | | | | | | |
| T1 | 0.51 | 0.00 | 0.31 | 0.00 | 0.00 | 1.27 | 0.88 |
| T2 | 2.54 | 4.26 | 1.33 | 6.89 | 30.25 | 1.79 | 1.97 |
| T3 | 14.05 | 110.68 | 1.71 | 9.88 | 31.51 | 6.62 | 4.66 |
| T4 | 106.42 | 243.67 | 507.77 | 436.66 | 271.92 | 14.02 | 65.73 |
| Lap Shear Strength | | | | | | | |
| T2 | 45.40 | 0.00 | Not Tested | 15.13 | 0.00 | 0.00 | 0.00 |
| T3 | 121.07 | 423.73 | Not Tested | 227.00 | 3359.60 | 45.40 | 45.40 |
| T4 | 10911.13 | 13468.67 | Not Tested | 151.33 | 4328.13 | 45.40 | 90.80 |

T1: tested immediately after lamination, no UV exposure;
T2: tested immediately after UV exposure;
T3: tested after 24 hours;
T4: tested after 7 days.

TABLE 3
T-Peel Strength and Lap Shear Strength of Laminate 2 of Examples 2-8

| | Ex 2 | Ex 3 | Ex 4 | Ex 5 | Ex 6 | Ex 7 | Ex 8 |
|---|---|---|---|---|---|---|---|
| T-Peel | | | | | | | |
| Strength | | | | | | | |
| T2 | 1.44 | 2.95 | 0.66 | 1.83 | 13.73 | 0.79 | 1.37 |
| T3 | 10.65 | 107.39 | 1.33 | 2.03 | 8.31 | 2.35 | 2.42 |
| T4 | 24.65 | 302.41 | 77.23 | 115.70 | 28.08 | 31.78 | 46.08 |
| Lap | | | | | | | |
| Shear | | | | | | | |
| Strength | | | | | | | |
| T2 | 196.73 | 302.67 | Not | 45.40 | 847.47 | 0.00 | 45.40 |
| | | | Tested | | | | |
| T3 | 10699.27 | 19400.93 | Not | 45.40 | 363.20 | 45.40 | 45.40 |
| | | | Tested | | | | |
| T4 | 25030.53 | Substrate | 46413.93 | 26937.33 | Not | 19809.53 | 33459.80 |
| | | Failure | | | Tested | | |

The above specification, examples and data describe the disclosure. Additional embodiments can be made without departing from the spirit and scope of the disclosure.

We claim:

1. A method of making an electronic assembly comprising:
(A) applying an adhesive composition to at least a portion of a first substrate, the adhesive composition comprising a moisture curable radiation curable prepolymer having a moisture curable functionality and radiation curable functionality; and
(B) contacting the adhesive on the first substrate with at least a portion of a second substrate, at least one of the first and second substrates comprising at least one electronic component prior to applying the adhesive.

2. The method of claim 1, wherein the adhesive composition further comprises an additional moisture curable prepolymer and/or an additional radiation curable component.

3. The method of claim 1, further comprising exposing the adhesive to radiation prior to or after step (B).

4. The method of claim 2, wherein the moisture-curable prepolymer is selected from the group consisting of an aliphatic isocyanate-terminated prepolymer, silanated-terminated prepolymer, and combinations thereof.

5. The method of claim 2, wherein the radiation curable component is selected from the group consisting of monomers, oligomers, and polymers of (meth)acrylate, and combinations thereof.

6. The method of claim 1, wherein the moisture curable functionality on the moisture curable radiation curable prepolymer is selected from the group consisting of an isocyanate, a silane, and combinations thereof.

7. The method of claim 1, wherein the radiation curable functionality on the moisture curable radiation curable prepolymer is selected from the group consisting of monomers, oligomers, and polymers of (meth)acrylate, and combinations thereof.

8. The method of claim 1, wherein the moisture curable radiation curable prepolymer is a reaction product of a moisture curable prepolymer and a radiation curable component.

9. The method of claim 1, wherein the first substrate and the second substrate can be of the same or different material, and independently selected from the group consisting of polyethylene, polyethylene terephthalate, polyethylene naphthalate, and combinations thereof.

10. The method of claim 1, wherein at least one of the first and second substrates is a flexible substrate.

11. The method of claim 1, wherein the electronic component is selected from the group consisting of a light-emitting diode (LED), a high brightness light-emitting diode (LED), an organic light-emitting diode (LED), a radio frequency identification (RFID) tag, an electrochromic display, an electrophoretic display, a battery, a sensor, a solar cell, and a photovoltaic cell.

12. The method of claim 1, wherein the adhesive further comprises a photoinitiator.

13. An electronic assembly comprising:
a first substrate;
a second substrate
at least one electronic component located between the first and the second substrates; and
an adhesive composition comprising a dual cure reaction product of a moisture curable radiation curable prepolymer having a moisture curable functionality and a radiation curable functionality,
wherein at least a portion of the first substrate is bonded to at least a portion of the second substrate by the adhesive composition.

14. The assembly of claim 13, wherein the adhesive composition comprises a dual cure reaction product of a moisture curable radiation curable prepolymer having a moisture curable functionality and a radiation curable functionality, an additional moisture curable prepolymer and/or an additional radiation curable component.

15. The assembly of claim 13, wherein the first substrate and the second substrate are of the same or different material, and are independently selected from the group consisting of polyethylene, polyethylene terephthalate, polyethylene naphthalate, and mixtures thereof.

16. The assembly of claim 13, wherein at least one of the first and the second substrates is a flexible substrate.

17. The assembly of claim 13, wherein the electronic component is part of a device selected from the group consisting of a light-emitting diode (LED), a high brightness light-emitting diode (LED), an organic light-emitting diode (LED), a radio frequency identification (RFID) tag, an electrochromic display, an electrophoretic display, a battery, a sensor, a solar cell, and a photovoltaic cell.

18. The assembly of claim 13, wherein the adhesive further comprises an additive selected from the group consisting of antioxidants, photoinitiators, plasticizers, tackifying agents, adhesion promoters, non-reactive resins, ultraviolet light stabilizers, catalysts, rheology modifiers, defoamers, biocides, corrosion inhibitors, dehydrators, organic solvents, colorants, fillers, surfactants, flame retardants, waxes, reactive plasticizers, thermoplastic polymers, tackifying agents, organofunctional silane adhesion promoters, and combinations thereof.

19. A method of making an electronic assembly comprising:
(A) providing an adhesive composition comprising
(i) a moisture-curable prepolymer; and
(ii) a radiation-curable component;
(B) applying the adhesive composition to at least a portion of a first substrate; and
(C) contacting the adhesive on the first substrate with at least a portion of a second substrate, at least one of the first and second substrates comprising an electronic component prior to applying the adhesive.

20. The method of claim 19, wherein the adhesive composition further comprises a photo initiator.

21. An electronic assembly comprising:
a first substrate;
a second substrate;
at least one electronic component in between the first and the second substrates; and
an adhesive composition comprising a dual cure reaction product of a moisture curable prepolymer and a radiation curable component,
wherein at least a portion of the first substrate is bonded to at least a portion of the second substrate by the adhesive composition.
